(19) United States
(12) Patent Application Publication
(10) Pub. No.: US 2025/0382708 A1
(43) Pub. Date: Dec. 18, 2025

(54) METHODS FOR USING NON-PLASMA MICROWAVE IN HYDROGEN AMBIENT TO MITIGATE MO NITRIDATION

(71) Applicant: Applied Materials, Inc., Santa Clara, CA (US)

(72) Inventors: Xianmin TANG, San Jose, CA (US); Avgerinos V. GELATOS, Scotts Valley, CA (US); Bencherki MEBARKI, Santa Clara, CA (US); Yoon Ah SHIN, Santa Clara, CA (US); Gaurav THAREJA, Santa Clara, CA (US); Jiajie CEN, Santa Clara, CA (US); Joung Joo LEE, San Jose, CA (US); Chi Hong CHING, Santa Clara, CA (US)

(21) Appl. No.: 19/209,368

(22) Filed: May 15, 2025

Related U.S. Application Data
(60) Provisional application No. 63/659,309, filed on Jun. 12, 2024.

(51) Int. Cl. C23C 16/56; C23C 16/06; C23C 16/34; C23C 16/455; H01L 21/768

(52) U.S. Cl. CPC C23C 16/56; C23C 16/06; C23C 16/34; C23C 16/45525; H01L 21/7685; H01L 21/76883

(57) ABSTRACT

Embodiments of the present disclosure generally relate to methods for using non-plasma microwave in hydrogen ambient to mitigate molybdenum (Mo) nitridation during metal-N film deposition. In some embodiments, a method for preparing a semiconductor device includes depositing a molybdenum (Mo) layer onto a substrate. The method further includes exposing the substrate to an air break to form a molybdenum oxide (MoOx) layer on the exposed portion of the Mo layer. The method further includes depositing a tantalum nitride (TaN) layer on the surface of the substrate. The method further includes performing a microwave assisted redox operation on the substrate to regenerate the Mo layer from the MoOx layer. Performing the microwave assisted redox operation includes positioning the substrate within a processing chamber, flowing a process gas into the processing chamber, and applying a non-plasma generating microwave energy to the process gas.

### CROSS-REFERENCE TO RELATED APPLICATIONS

This application claims benefit of U.S. Provisional Patent Application Ser. No. 63/659,309, filed Jun. 12, 2024, which is herein incorporated by reference in its entirety.

### BACKGROUND

### Field

Embodiments of the present disclosure generally relate to methods for using non-plasma microwave in hydrogen ambient to mitigate molybdenum (Mo) nitridation during metal-N film deposition. Embodiments of the present disclosure also relate to methods for molybdenum deposition with improved contact resistivity in middle-of-line (MOL) and back-end-of-line (BEOL) integration flows.

### Description of the Related Art

Semiconductor devices continuously improve their integration density through design-rule shrinkage. As feature size decreases, resistance increases and results in degradation of device characteristics, such as RC delay. Therefore, new materials such as molybdenum (Mo), which have a low resistivity, can be used to form low resistance conductive features in a semiconductor device is needed.

Direct replacement with Mo in the integration flow results in lower resistance that shows initial integration benefit. However, resistance starts to increase after thermal treatment during BEOL integration. Extensive studies show that nitrogen diffusion within a device structure, which reacts with Mo during a thermal treatment process, is a major root cause of the molybdenum nitride (MoN) formation. Such MoN formation causes the resistance in the device structure to increase. A source of the nitrogen is provided during an ammonia (NH₃) soak step during the thermal atomic layer deposition (ALD) process to deposit a tantalum nitride (TaN) layer over a surface of the semiconductor device. Since it is very difficult to remove the nitrogen source during BEOL integration processes, there is a need to mitigate Mo nitridation through new methods in the integration flow.

### SUMMARY

Embodiments of the present disclosure generally relate to methods for using non-plasma microwave in hydrogen ambient to mitigate molybdenum (Mo) nitridation during metal-N film deposition. Embodiments of the present disclosure also relate to methods for molybdenum deposition with improved contact resistivity in middle-of-line (MOL) and back-end-of-line (BEOL) integration flows.

In some embodiments, a method for preparing a semiconductor device includes depositing a molybdenum (Mo) layer onto a substrate. A portion of the Mo layer is exposed at a surface of the substrate. The method further includes exposing the substrate to an air break to form a molybdenum oxide (MoOx) layer on the exposed portion of the Mo layer. The method further includes depositing a tantalum nitride (TaN) layer on the surface of the substrate. The TaN layer contacts the MoOx layer. The method further includes performing a microwave assisted redox operation on the substrate to regenerate the Mo layer from the MoOx layer. Performing the microwave assisted redox operation includes positioning the substrate within a processing chamber, flowing a process gas into the processing chamber, and applying a non-plasma generating microwave energy to the process gas.

In some embodiments, a method for preparing a semiconductor device includes depositing a molybdenum (Mo) layer onto a substrate. A portion of the Mo layer is exposed at a surface of the substrate. The Mo layer is deposited in a first processing chamber. The method further includes exposing the substrate to an air break to form a molybdenum oxide (MoOx) layer on the exposed portion of the Mo layer. The method further includes depositing a tantalum nitride (TaN) layer on the surface of the substrate. The TaN layer contacts the MoOx layer. The TaN layer is deposited in a second processing chamber. The method further includes performing a microwave assisted redox operation on the substrate to regenerate the Mo layer from the MoOx layer. Performing the microwave assisted redox operation includes positioning the substrate within a third processing chamber, flowing a process gas into the third processing chamber, and applying a non-plasma generating microwave energy to the process gas.

In some embodiments, a method for preparing a semiconductor device includes depositing a metal layer onto a substrate. A portion of the metal layer is exposed at a surface of the substrate. The method further includes exposing the substrate to an air break to form a metal oxide layer on the exposed portion of the metal layer. The method further includes depositing a barrier layer on the surface of the substrate. The barrier layer contacts the metal oxide layer. The method further includes performing a microwave assisted redox operation on the substrate to regenerate the metal layer from the metal oxide layer. Performing the microwave assisted redox operation includes positioning the substrate within a processing chamber, flowing a process gas into the processing chamber, and applying a non-plasma generating microwave energy to the process gas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic top view of a multi-chamber processing system, according to embodiments described herein.

FIG. 2A is a schematic of a processing chamber that includes a microwave source, in accordance with an embodiment.

FIG. 2B is a schematic of a solid state microwave emission module, in accordance with an embodiment.

FIG. 2C is a perspective view illustration of a source array for a microwave source, in accordance with an embodiment.

FIG. 2D is a cross-sectional illustration of a processing chamber for processing a semiconductor structure, in accordance with an embodiment.

FIG. 3 is a flow diagram depicting a method of processing a semiconductor structure, in accordance with an embodiment.

FIG. 4A is a cross-sectional illustration of a semiconductor structure, in accordance with an embodiment.

FIG. 4B is a cross-sectional illustration of a semiconductor structure, in accordance with an embodiment.

FIG. 4C is a cross-sectional illustration of a semiconductor structure, in accordance with an embodiment.

FIG. 4D is a cross-sectional illustration of a semiconductor structure, in accordance with an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods disclosed herein incorporate various semiconductor fabrication operations, which are organized to mitigate Mo nitridation. The method includes depositing metal layer onto a semiconductor structure, exposing the semiconductor structure to an air break to form a metal oxide layer on the metal layer, depositing a barrier layer over the surface of the semiconductor structure, performing a microwave assisted redox on the semiconductor structure in a hydrogen environment. The process disclosed herein integrates the formation of a metal oxide (e.g., MoOx) layer on an exposed surface of the metal layer to prevent nitrogen based reagents from reacting with the metal layer to form MoN. Furthermore, the method disclosed herein integrates a microwave assisted redox operation to allow for reduction of the metal oxide layer (e.g., MoOx) to regenerate the initial metal layer without affecting a barrier layer deposited thereon.

### Processing System Example

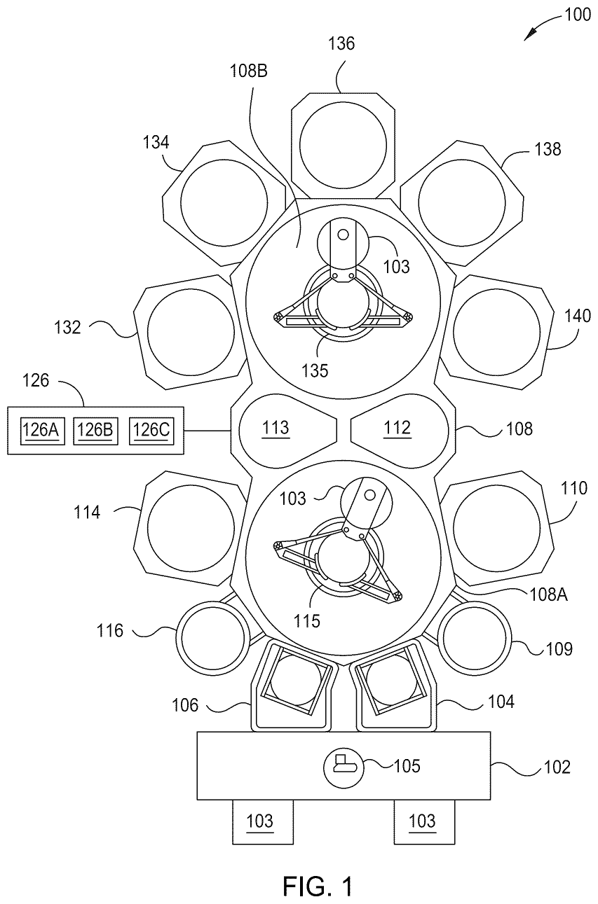

FIG. 1 illustrates a schematic representation of a processing system 100 for use with one or more embodiments of the disclosure. As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a low pressure (for example, less than or equal to about 300 Torr) or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

Examples of a processing system that may be suitably modified in accordance with the teachings provided include the Endura®, Producer® or Centura® integrated processing systems or other suitable processing systems commercially available from Applied Materials, Inc., located in Santa Clara, California (CA), United States of America. One may envision that other processing systems, including those from other manufacturers, may be adapted to benefit from aspects described.

FIG. 1 is a schematic top view of the substrate processing system 100 (also referred to as a “processing platform”), according to embodiments described herein. The substrate processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116, and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138, and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138, 140 are a PVD chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective CVD or ALD deposition processes. In one example, the processing chambers 132, 134, 136, 138, or 140 may be a Volta™ CVD/ALD chamber, or Encore™ PVD chambers available from Applied Materials of Santa Clara, Calif.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (that is, ˜10⁻³ Pa). However, some high-vacuum systems may operate below near 10⁻⁷ Torr (that is, ˜10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with a memory 126B (for example, non-volatile memory) and support circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the computer instruction code is executed by the CPU 126A, the CPU 126A controls the chambers to perform processes in accordance with the various methods.

As will be described further below, in one or more embodiments of the substrate processing sequence described herein, all of the processes are performed under vacuum within the processing system 100. In one example of the processing system 100, a remote-plasma-source (RPS) cleaning process is performed in chamber 110, a precleaning process is performed in chamber 114, and one or more of a deposition, an etching, and/or a thermal processing process is performed in at least one of the chambers 132, 134, 136, 138, and 140. In one example, the remote plasma (RPS) assisted process performed in chamber 110 is performed in a processing chamber, such as Aktiv™ Preclean (APC) chamber available from Applied Materials of Santa Clara, Calif. In another example, the processing chambers 132, 134, 136, 138, or 140 may be a Volta™ CVD/ALD chamber, or Encore™ PVD chambers available from Applied Materials of Santa Clara, Calif.

In another example of the processing system 100, a remote-plasma-source (RPS) cleaning process and a precleaning process are both performed in at least one of the chambers 110 and 114, and one or more of a deposition, an etching, and/or a thermal processing process is performed in at least one of the chambers 132, 134, 136, 138, and 140. In one example, the processing chambers 132, 134, 136, 138, or 140 may be a Volta™ CVD/ALD chamber, or Encore™ PVD chambers available from Applied Materials of Santa Clara, Calif.

### Processing Chamber Example

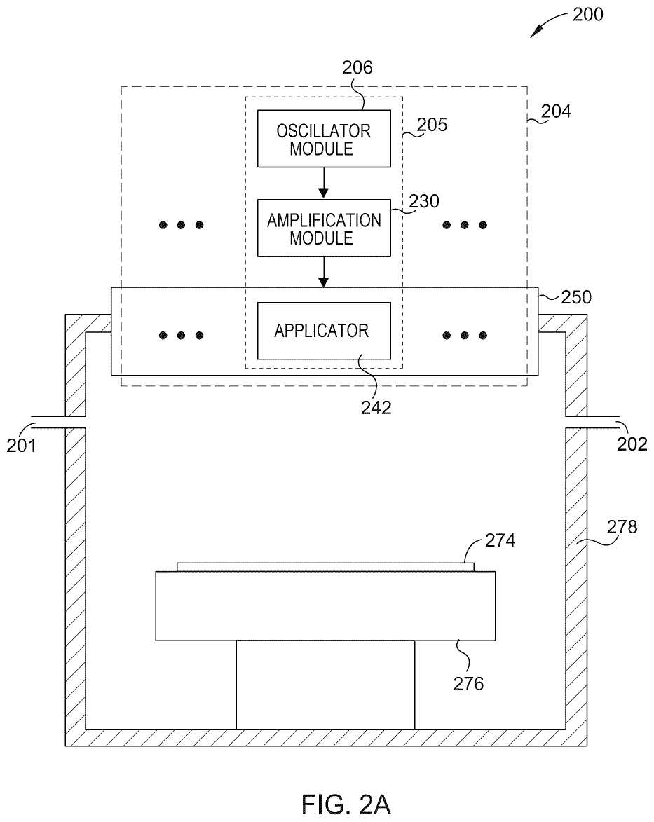

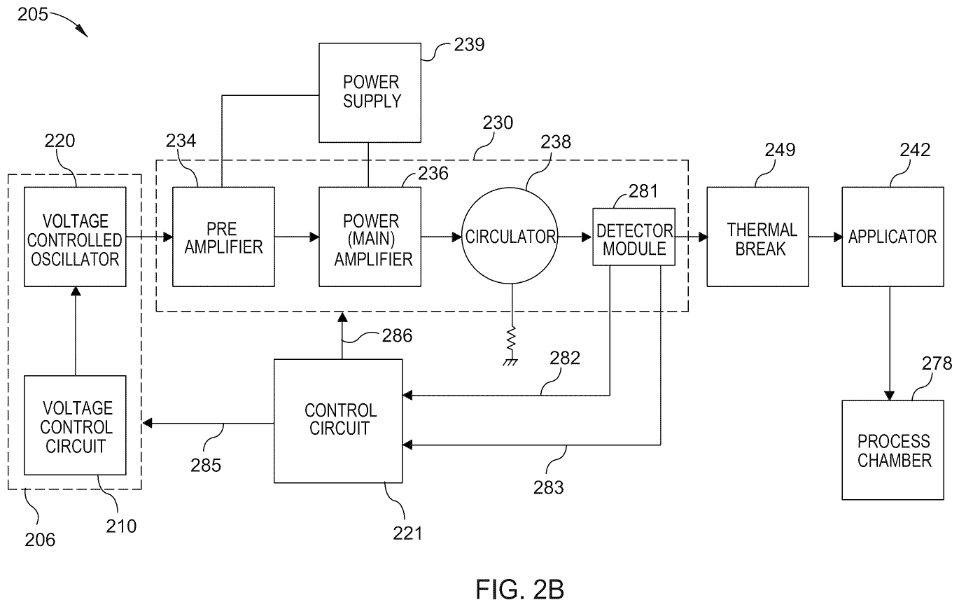

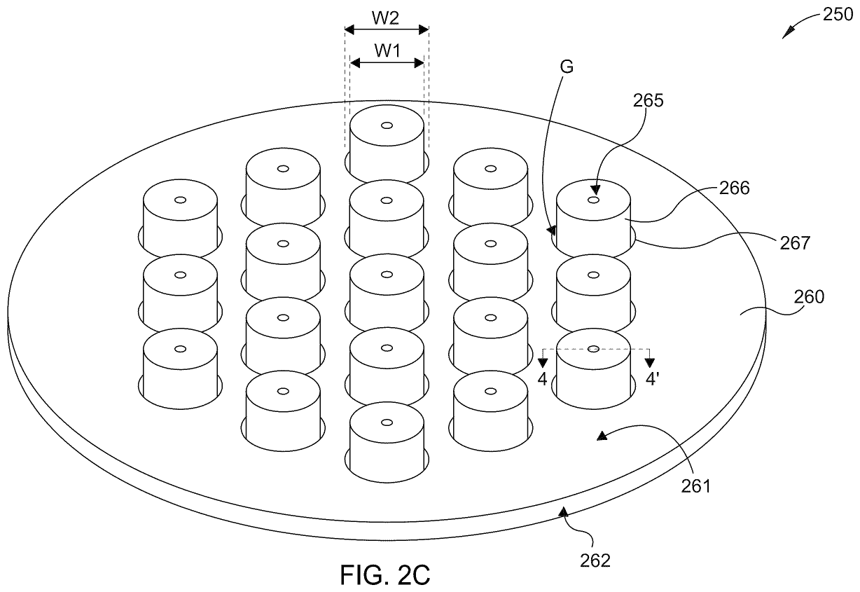

Referring now to FIGS. 2A-2D, a series of illustrations depicting an example of a microwave processing tool 200 is shown, in accordance with an embodiment. The microwave processing tool 200 is configured to deliver microwave energy to a processing region of the process chamber to perform a low temperature preclean process on a substrate.

Referring now to FIG. 2A, a cross-sectional illustration of a microwave processing tool 200 (referred to as processing tool 200 for short) is shown, according to an embodiment. In some embodiments, the processing tool 200 may be a processing tool suitable for any type of processing operation that requires the delivery of microwave energy. In some embodiments, one or more of the chambers 110 and 114, or even chambers 132-140, may include the processing tool 200. The processing tool may emit high-frequency electromagnetic radiation in the form of microwave energy. In some embodiments, “High-frequency” may refer to frequencies between 300 MHz and 1000 GHz.

Generally, embodiments include a processing tool 200 that includes a chamber 278. In processing tool 200, the chamber 278 may be a vacuum chamber. A vacuum chamber may include a pump (not shown) for removing gases from the chamber to provide the desired vacuum. Additional embodiments may include a chamber 278 that includes one or more gas lines 201 for providing processing gases into the chamber 278 and exhaust lines 202 for removing byproducts from the chamber 278. While not shown, it is to be appreciated that gas may also be injected into the chamber 278 through a source array 250 (e.g., as a showerhead) for evenly distributing the processing gases over a substrate 274.

In an embodiment, the substrate 274 may be supported on a chuck 276. For example, the chuck 276 may be any suitable chuck, such as an electrostatic chuck. The chuck 276 may also include cooling lines and/or a heater to provide temperature control to the substrate 274 during processing. Due to the modular configuration of the high-frequency emission modules described herein, embodiments allow for the processing tool 200 to accommodate any sized substrate 274. For example, the substrate 274 may be a semiconductor wafer (e.g., 200 mm, 300 mm, 450 mm, or larger). Alternative embodiments also include substrates 274 other than semiconductor wafers. For example, embodiments may include a processing tool 200 configured for processing glass substrates (e.g., for display technologies).

According to an embodiment, the processing tool 200 includes a modular high-frequency emission source 204. The modular high-frequency emission source 204 may comprise an array of high-frequency emission modules 205. In an embodiment, each high-frequency emission module 205 may include an oscillator module 206, an amplification module 230, and an applicator 242. As shown, the applicators 242 are schematically shown as being integrated into the source array 250.

In an embodiment, the oscillator module 206 and the amplification module 230 may comprise electrical components that are solid state electrical components. In an embodiment, each of the plurality of oscillator modules 206 may be communicatively coupled to different amplification modules 230. For example, each oscillator module 206 may be electrically coupled to a single amplification module 230. In an embodiment, the plurality of oscillator modules 206 may generate incoherent electromagnetic radiation. Accordingly, the electromagnetic radiation induced in the chamber 278 will not interact in a manner that results in an undesirable interference pattern.

In an embodiment, each oscillator module 206 generates high frequency electromagnetic radiation that is transmitted to the amplification module 230. After processing by the amplification module 230, the electromagnetic radiation is transmitted to the applicator 242. In an embodiment, the applicators 242 each emit electromagnetic radiation into the chamber 278. In some embodiments, the applicators 242 couple the electromagnetic radiation to the processing gases in the chamber 278 to provide energy thereto, without forming a plasma. In one example, plasma formation can be detected by use of optical emission spectroscopy techniques or even the electrical detection of a formed plasma potential or plasma impedance.

Referring now to FIG. 2B, a schematic of the solid state high-frequency emission module 205 is shown, in accordance with an embodiment. In an embodiment, the high-frequency emission module 205 comprises the oscillator module 206. The oscillator module 206 may include a voltage control circuit 210 for providing an input voltage to a voltage controlled oscillator 220 in order to produce high-frequency electromagnetic radiation at a desired frequency. The voltage controlled oscillator 220 is an electronic oscillator whose oscillation frequency is controlled by the input voltage. According to an embodiment, the input voltage from the voltage control circuit 210 results in the voltage controlled oscillator 220 oscillating at a desired frequency.

According to an embodiment, the electromagnetic radiation is transmitted from the voltage controlled oscillator 220 to an amplification module 230. The amplification module 230 may include a driver/pre-amplifier 234, and a main power amplifier 236 that are each coupled to a power supply 239. According to an embodiment, the amplification module 230 may operate in a pulse mode. For example, the amplification module 230 may have a duty cycle between 1% and 99%. In a more particular embodiment, the amplification module 230 may have a duty cycle between approximately 15% and 50%.

In an embodiment, the electromagnetic radiation may be transmitted to a thermal break 249 and the applicator 242 after being processed by the amplification module 230. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to a control circuit module 221. It is to be appreciated that the detector module 281 may be located at one or more different locations in the system (e.g., between the circulator 238 and the thermal break 249). In an embodiment, the control circuit module 221 interprets the forward power 283 and the reflected power 282, and determines the level for a control signal 285 that is communicatively coupled to the oscillator module 206 and the level for a control signal 286 that is communicatively coupled to the amplification module 230. In an embodiment, control signal 285 adjusts the oscillator module 206 to optimize the high-frequency radiation coupled to the amplification module 230. In an embodiment, the control signal 286 adjusts the amplification module 230 to optimize the output power coupled to the applicator 242 through the thermal break 249. In an embodiment, the feedback control of the oscillator module 206 and the amplification module 230, in addition to the tailoring of the impedance matching in the thermal break 249, may allow for the level of the reflected power to be less than approximately 5% of the forward power. In some embodiments, the feedback control of the oscillator module 206 and the amplification module 230 may allow for the level of the reflected power to be less than approximately 2% of the forward power.

Accordingly, embodiments allow for an increased percentage of the forward power to be coupled into the processing chamber 278, and increases the available power provided to the process gases disposed within the processing volume. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator.

Referring now to FIG. 2C, a perspective view illustration of a source array 250 is shown, in accordance with an embodiment. In an embodiment, the source array 250 comprises a dielectric plate 260. A plurality of cavities 267 are disposed into a first surface 261 of the dielectric plate 260. The cavities 267 pass through to a second surface 262 of the dielectric plate 260. The source array 250 may further include a plurality of dielectric resonators 266. Each of the dielectric resonators 266 may be in a different one of the cavities 267. Each of the dielectric resonators 266 may comprise a hole 265 in the axial center of the dielectric resonator 266.

In an embodiment, the dielectric resonators 266 may have a first width W1, and the cavities 267 may have a second width W2. The first width W1 of the dielectric resonator 266 is smaller than the second width W2 of the cavities 267. The difference in the widths provides a gap G between a sidewall of the dielectric resonators 266 and a sidewall of the cavity 267. In the illustrated embodiment, each of the dielectric resonators 266 are shown as having a uniform width W1. However, it is to be appreciated that not all dielectric resonators 266 of a source array 250 need to have the same dimensions.

Referring now to FIG. 2D, a cross-sectional illustration of a processing tool 200 that includes an assembly 270 is shown, in accordance with an embodiment. In an embodiment, the processing tool comprises a chamber 278 that is sealed by an assembly 270. For example, the assembly 270 may rest against one or more O-rings 203 to provide a vacuum seal to an interior chamber volume 207 of the chamber 278. In other embodiments, the assembly 270 may interface with the chamber 278. That is, the assembly 270 may be part of a lid that seals the chamber 278. In an embodiment, the processing tool 200 may comprise a plurality of processing volumes (which may be fluidically coupled together), with each processing volume having a different assembly 270. In an embodiment, a chuck 276 or the like may support a substrate 274. The substrate 274 may be a distance D from the assembly 270. In an embodiment, the interior chamber volume 207 may be suitable for delivering microwave energy to a process gas disposed within the chamber 278. That is, the chamber 278 may be a vacuum chamber.

In an embodiment, the assembly 270 comprises a source array 250 and a housing 272. The source array 250 may comprise a dielectric plate 260 and a plurality of dielectric resonators 266 extending up from the dielectric plate 260. Cavities 267 into the dielectric plate 260 may surround each of the dielectric resonators 266. Sidewalls of the cavity 267 are separated from the sidewall of the dielectric resonator 266 by a gap G. The dielectric plate 260 and the dielectric resonators 266 of the source array 250 may be a monolithic structure (as shown in FIG. 20), or the dielectric plate 260 and the dielectric resonators 266 may be discrete components.

The housing 272 include rings 231 that fit into the gaps G. In an embodiment, the rings 231 and the conductive body 273 of the housing 272 are a monolithic structure (as shown in FIG. 20), or the conductive body 273 and the rings 231 may be discrete components. The housing 272 may have openings sized to receive the dielectric resonators 266. In an embodiment, monopole antennas 288 may extend into holes in the dielectric resonators 266. The monopole antennas 288 are each electrically coupled to power sources (e.g., high-frequency emission modules 205).

### Substrate Processing Sequences

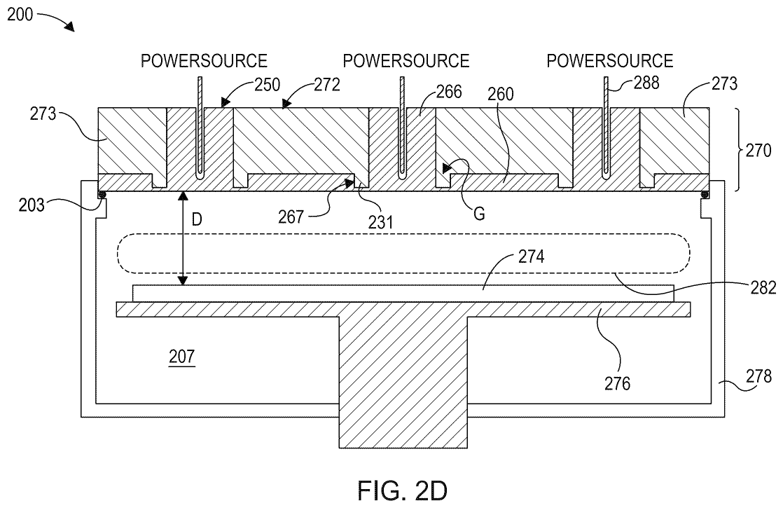

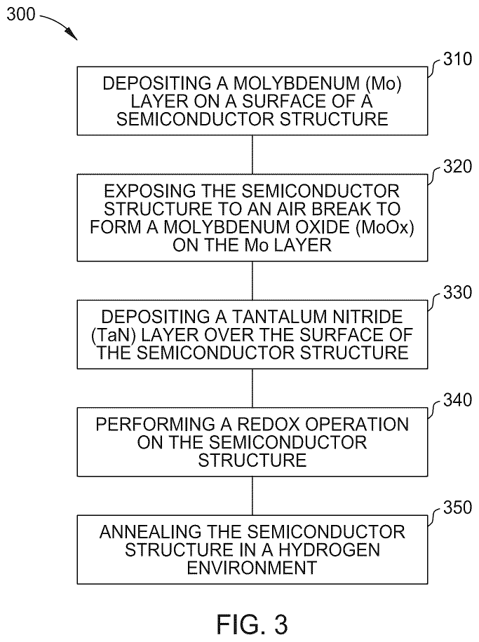

FIG. 3 depicts a process flow diagram of a method 300 of processing a substrate to, for example, form middle-of-line (MOL) and back-end-of-line (BEOL) structures, according to one or more embodiments of the present disclosure. The method 300 includes depositing metal layer onto the semiconductor structure (operation 310), exposing the semiconductor structure to an air break to form a metal oxide layer on the metal layer (operation 320), depositing a barrier layer over the surface of the semiconductor structure (operation 330), performing a redox on the semiconductor structure (operation 340), and annealing the semiconductor structure in a hydrogen environment (operation 350). Each of the operations of the method 300 may be performed independently in separate processing chambers, or in the same processing chamber.

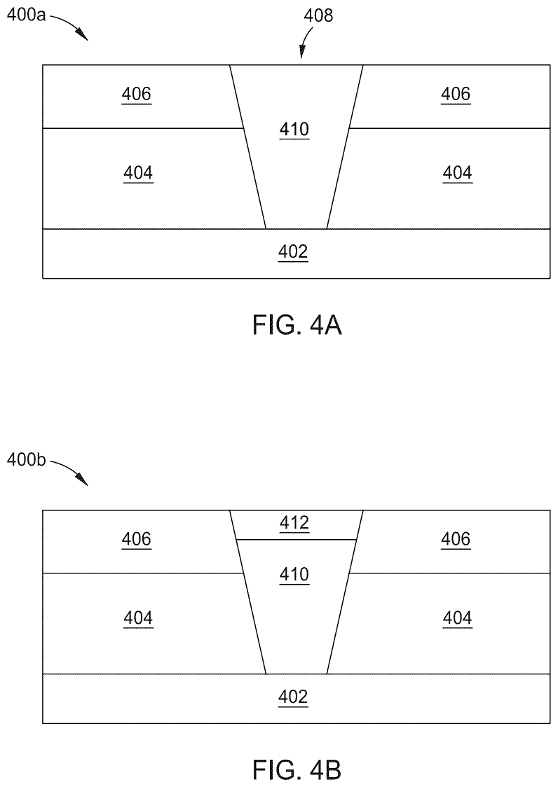

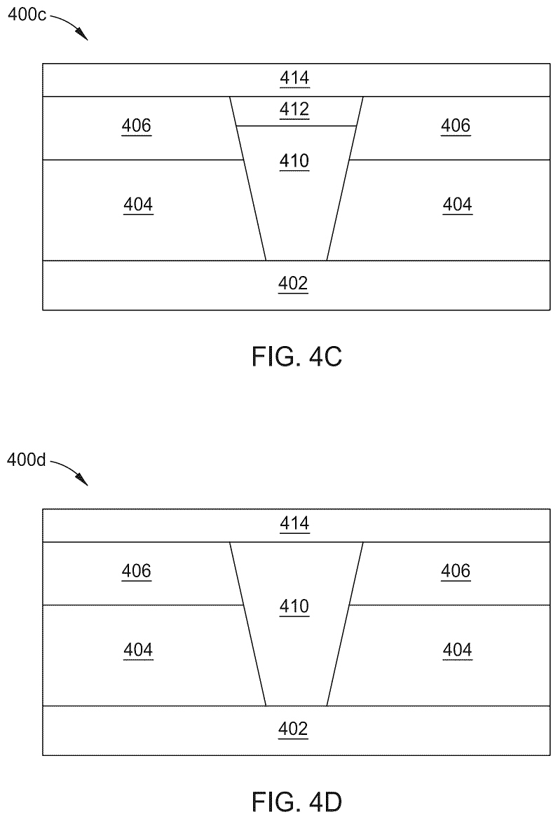

FIGS. 4A-4D illustrate cross-sectional views of a semiconductor structure (e.g., 400a, 400b, 400c, and 400d respectively) in accordance with one or more embodiments described herein. Although FIGS. 4A-4D are described in relation to the method 300, the structures disclosed in FIGS. 4A-4D are not limited to the method 300, but instead may stand alone as structures independent of the method 300. Similarly, although the method 300 is described in relation to FIGS. 4A-4D, the method 300 is not limited to the structures disclosed in FIGS. 4A-4D but instead may stand alone independent of the structures disclosed in FIGS. 4A-4D. It should be understood that FIGS. 4A-4D illustrate only partial schematic views of the semiconductor device structure (e.g., 400a, 400b, 400c, and 400d respectively), and the semiconductor device structure (e.g., 400a, 400b, 400c, and 400d respectively) may contain any number of transistors or other devices and additional materials having aspects as illustrated in the figures. It should also be noted that although the method 300 illustrated in FIG. 3 is described sequentially, other process sequences that include one or more operations that have been omitted and/or added, and/or has been rearranged in another desirable order, fall within the scope of the embodiments of the disclosure provided herein.

The term “substrate” and/or “semiconductor structure” as used herein refers to a layer of material that serves as a basis for subsequent processing operations. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

Referring back to the method 300, at operation 310 a metal layer 410 is deposited on a semiconductor structure, such as the semiconductor structure 400a illustrated in FIG. 4A. The semiconductor structure 400a may include a tungsten (W) layer 402, a silicon nitride (SiN) layer 404, and/or a silicon oxide (SiO) layer 406. In some embodiments, the semiconductor structure 400a includes a feature 408 (e.g., a gap, a trench, a via, and/or the like) disposed therein. In at least one embodiment, the metal layer 410 is deposited within the feature 408 of the semiconductor structure 400a. The metal layer 410 may be deposited on the surface of the semiconductor structure 400a and/or within a feature 408 disposed therein via any one or more suitable processes (e.g., atomic layer deposition (ALD), chemical vapor deposition (CVD), physical vapor deposition (PVD), plasma enhanced chemical vapor deposition (PECVD), and the like) and may be performed in any one or more suitable processing chambers, such as those described above. In at least one embodiment, the metal layer 410 may be deposited within a feature 408 disposed within the semiconductor structure 400a via a process developed to provide a bottom-up metal deposition profile. The metal layer 410 may have a thickness of about 100 Å to about 500 Å, such as about 200 Å to about 400 Å, such as about 250 Å to about 350 Å, alternatively about 100 Å to about 200 Å, alternatively about 200 Å to about 250 Å, alternatively about 250 Å to about 300 Å, alternatively about 300 Å to about 350 Å, alternatively about 350 Å to about 400 Å, alternatively about 400 Å to about 500 Å. In some embodiments, a portion of the metal layer 410 is exposed on a surface of the semiconductor structure 400a.

The metal layer 410 may include any one or more suitable metal materials, such as a metal material capable of forming a metal oxide when exposed to an oxidative environment (e.g., air). The metal layer 410 may include one or more of molybdenum (Mo), tungsten (W), ruthenium (Ru), copper (Cu), cobalt (Co), tantalum (Ta), titanium (Ti), or combinations thereof. In some embodiments, the metal layer 410 includes Mo. The shape and/or orientation of the metal layer 410 may be predicated on the shape and/or configuration of the feature 408.

In operation 320 of the method 300, the semiconductor structure 400a is exposed to an air break (e.g., introducing the semiconductor structure 400a to atmosphere) to convert a portion of the metal layer 410 to a metal oxide layer 412. As illustrated by the semiconductor structure 400b shown in FIG. 4B. The metal oxide layer 412 may form at, on, and/or in the portion of the metal layer 410 that is exposed on the surface of the semiconductor structure 400a. In one or more embodiments, the metal oxide layer 412 includes molybdenum oxide (MoOx).

In some embodiments, the metal oxide layer 412 has a thickness of about 10 Å to about 30 Å, such as about 15 Å to about 25 Å, such as about 18 Å to about 22 Å, alternatively about 10 Å to about 15 Å, alternatively about 15 Å to about 18 Å, alternatively about 18 Å to about 20 Å, alternatively about 20 Å to about 22 Å, alternatively about 22 Å to about 25 Å, alternatively about 25 Å to about 30 Å. The metal material within the metal layer 410 is converted to the metal oxide within the metal oxide layer 412.

In operation 330 of the method 300, a barrier layer 414 is deposited over the surface of the semiconductor structure 400b, as illustrated by the semiconductor structure 400c shown in FIG. 4C. The barrier layer 414 may be deposited over the surface of the semiconductor structure 400b via any one or more suitable deposition processes previously described and/or within the corresponding processing chamber. In some embodiments, the barrier layer 414 is a tantalum nitride (TaN) layer deposited over the surface of the semiconductor structure 400b via an ALD process, such as a thermal ALD process. The barrier layer 414 may be deposited over the surface of the semiconductor structure 400b, such that the barrier layer 414 is in contact with the exposed portion of the metal oxide layer 412 on the surface of the semiconductor structure 400b, as illustrated by the semiconductor structure 400c shown in FIG. 4C. In other words, the metal layer 410 is separated from the barrier layer 414 by the metal oxide layer 412.

In a typical ALD process, alternating pulses or flows of “A” precursor and “B” precursor can be used to deposit a film. The alternating exposure of the surface to reactants “A” and “B” is continued until the desired thickness film is reached. However, instead of pulsing the reactants, the gases can flow simultaneously from one or more gas delivery head or nozzle and the substrate and/or gas delivery head can be moved such that the substrate is sequentially exposed to each of the reactive gases. Of course, the aforementioned ALD cycles are merely exemplary of a wide variety of ALD process cycles in which a deposited layer is formed by alternating layers of precursors and co-reactants. In at least one embodiments, the reactants used to form the barrier layer include a tantalum based precursor and a nitrogen containing precursor.

In some embodiments, the ALD process temperature may be in a range from about 200° C. to about 500° C., such as about 225° C. to about 400° C., such as about 250° C. to about 300° C., such as about 270° C. to about 280° C., alternatively about 200° C. to about 225° C., alternatively about 225° C. to about 250° C., alternatively about 250° C. to about 275° C., alternatively about 275° C. to about 280° C., alternatively about 280° C. to about 300° C., alternatively about 300° C. to about 400° C., alternatively about 400° C. to about 500° C., alternatively about 425° C. to about 475° C., alternatively about 425° C. to about 450° C., alternatively about 450° C. to about 475° C. The pressure within the processing chamber during the ALD process may be in the range of about 10 mTorr to about 760 Torr, such as 10 Torr to about 760 Torr, such as about 250 Torr to about 760 Torr, such as about 250 Torr to about 530 Torr, alternatively about 10 Torr to about 100 Torr, alternatively about 100 Torr to about 250 Torr, alternatively about 250 Torr to about 400 Torr, alternatively about 400 Torr to about 550 Torr, alternatively about 500 Torr to about 760 Torr, alternatively about 100 Torr to about 760 Torr.

In some embodiments, the ALD-deposited TaN layer is deposited from one or more tantalum precursors, such as pentakis(dimethylamino)tantalum, and one or more nitrogen precursors such as ammonia (NH₃). In one or more embodiments, the ALD-deposition may also include a carrier gas, such as He and/or N₂. In some embodiments, the N₂ gas may also act as a reactive nitrogen precursor. In some embodiments, the tantalum precursors may be supplied as a process gas to the processing chamber. In at least one embodiment, the tantalum precursor and nitrogen precursor may be supplied sequentially as process gases to the processing chamber. In at least one embodiment, the tantalum precursor may be supplied as a process gas to the processing chamber, followed by a purge of the processing chamber with the carrier gas, and then the nitrogen precursor may be supplied as a process gas to the processing chamber.

The tantalum precursor may be supplied to the processing chamber at a flow rate of about 10 sccm to about 5000 sccm, such as about 50 sccm to about 2500 sccm, such as about 100 sccm to about 1000 sccm, such as about 500 sccm to about 700 sccm, alternatively about 10 sccm to about 50 sccm, alternatively about 50 sccm to about 100 sccm, alternatively about 100 sccm to about 500 sccm, alternatively about 500 sccm to about 600 sccm, alternatively about 600 sccm to about 700 sccm, alternatively about 700 sccm to about 1000 sccm, alternatively about 1000 sccm to about 2500 sccm, alternatively about 2500 sccm to about 5000 sccm. The tantalum precursor may be purged from the processing chamber by supplying the carrier gas thereto at a flow rate of about 1000 sccm to about 10000 sccm, such as about 2000 sccm to about 8000 sccm, such as about 3000 sccm to about 6000 sccm, such as about 4000 sccm to about 5000 sccm, alternatively about 1000 sccm to about 2000 sccm, alternatively about 2000 sccm to about 3000 sccm, alternatively about 3000 sccm to about 4000 sccm, alternatively about 4000 sccm to about 4500 sccm, alternatively about 4500 sccm to about 5000 sccm, alternatively about 5000 sccm to about 6000 sccm, alternatively about 6000 sccm to about 8000 sccm, alternatively about 8000 sccm to about 10000 sccm. The nitrogen-containing precursor may be supplied to the processing chamber at a flow rate of about 10 sccm to about 10000 sccm, such as about 50 sccm to about 5000 sccm, such as about 100 sccm to about 2500 sccm, such as about 500 sccm to about 1500 sccm, such as about 800 sccm to about 1000 sccm, alternatively about 10 sccm to about 50 sccm, alternatively about 50 sccm to about 100 sccm, alternatively about 100 sccm to about 500 sccm, alternatively about 500 sccm to about 800 sccm, alternatively about 800 sccm to about 900 sccm, alternatively about 900 sccm to about 1000 sccm, alternatively about 1000 sccm to about 1500 sccm, alternatively about 1500 sccm to about 2500 sccm, alternatively about 2500 sccm to about 5000 sccm, alternatively about 5000 sccm to about 10000 sccm. The nitrogen-containing precursor may be purged from the processing chamber by supplying the carrier gas thereto at a flow rate of about 1000 sccm to about 10000 sccm, such as about 2000 sccm to about 8000 sccm, such as about 3000 sccm to about 6000 sccm, such as about 4000 sccm to about 5000 sccm, alternatively about 1000 sccm to about 2000 sccm, alternatively about 2000 sccm to about 3000 sccm, alternatively about 3000 sccm to about 4000 sccm, alternatively about 4000 sccm to about 4500 sccm, alternatively about 4500 sccm to about 5000 sccm, alternatively about 5000 sccm to about 6000 sccm, alternatively about 6000 sccm to about 8000 sccm, alternatively about 8000 sccm to about 10000 sccm. The ALD process may be continued for any suitable number of cycles so as to form a TaN layer of a predetermined thickness.

In some embodiments, the barrier layer 414 is deposited at a deposition rate of about 0.1 Å/cycle to about 3 Å/cycle, such as about 0.2 Å/cycle to about 2 Å/cycle, such as about 0.4 Å/cycle to about 1 Å/cycle, such as about 0.5 Å/cycle to about 0.7 Å/cycle, alternatively about 0.1 Å/cycle to about 0.2 Å/cycle, alternatively about 0.2 Å/cycle to about 0.4 Å/cycle, alternatively about 0.4 Å/cycle to about 0.5 Å/cycle, alternatively about 0.5 Å/cycle to about 0.6 Å/cycle, alternatively about 0.6 Å/cycle to about 0.7 Å/cycle, alternatively about 0.7 Å/cycle to about 1 Å/cycle, alternatively about 1 Å/cycle to about 2 Å/cycle, alternatively about 2 Å/cycle to about 3 Å/cycle. The barrier layer 414 may have a thickness of about 1 Å to about 100 Å, such as about 5 Å to about 75 Å, such as about 10 Å to about 50 Å, such as about 15 Å to about 25 Å, alternatively about 1 Å to about 5 Å, alternatively about 5 Å to about 10 Å, alternatively about 10 Å to about 15 Å, alternatively about 15 Å to about 20 Å, alternatively about 20 Å to about 25 Å, alternatively about 25 Å to about 50 Å, alternatively about 50 Å to about 75 Å, alternatively about 75 Å to about 100 Å. In at least one embodiment, the barrier layer is deposited via an ALD process using 1 cycle to 50 cycles, such as 5 cycles to 30 cycles, such as 10 cycles to 20 cycles, alternatively about 1 cycle to 5 cycles, alternatively 5 cycles to 10 cycles, alternatively 10 cycles to 15 cycles, alternatively 15 cycles to 20 cycles, alternatively 20 cycles to 30 cycles, alternatively 30 cycles to 50 cycles.

In operation 340 of the method 300, the semiconductor structure 400c is subjected to a redox operation to convert the metal oxide material within the metal oxide layer 412 to its respective metal material thereby regenerating the initial metal layer 410. The redox operation may be performed in any suitable processing chamber, such as the microwave processing tool 200 described above.

The redox operation may include flowing a process gas into the processing chamber. The process gas may include hydrogen (H₂), Ar, He, water (H₂O), or a combination thereof. In at least one embodiment, the process gas includes H₂. The process gas may be flowed into the processing chamber at a gas flow rate of about 0.01 sccm to about 45,000 sccm, such as about 100 sccm to about 45,000 sccm, such as about 1,000 sccm to about 45,000 sccm, such as about 2,000 sccm to about 45,000 sccm, such as about 3,000 sccm to about 45,000 sccm, such as about 10,000 sccm to about 45,000 sccm, alternatively about 0.01 sccm to about 100 sccm, alternatively about 100 sccm to about 1,000 sccm, alternatively about 1,000 sccm to about 2,000 sccm, alternatively about 2,000 sccm to about 3,000 sccm, alternatively about 3,000 sccm to about 10,000 sccm, alternatively about 10 sccm to about 2,000 sccm. In at least one embodiment, the process gas is flown into the processing chamber continuously throughout the duration of the redox operation.

In some embodiments, the temperature within the processing chamber during the redox operation is about 100° C. to about 500° C., such as about 150° C. to about 450° C., such as about 200° C. to about 400° C., such as about 250° C. to about 350° C., alternatively about 100° C. to about 150° C., alternatively about 150° C. to about 200° C., alternatively about 200° C. to about 250° C., alternatively about 250° C. to about 300° C., alternatively about 300° C. to about 350° C., alternatively about 350° C. to about 400° C., alternatively about 400° C. to about 450° C., alternatively about 450° C. to about 500° C. The pressure within the processing chamber during the redox operation may be from about 10 Torr to about 760 Torr, such as about 250 Torr to about 760 Torr, such as about 250 Torr to about 530 Torr, alternatively about 10 Torr to about 100 Torr, alternatively about 100 Torr to about 250 Torr, alternatively about 250 Torr to about 400 Torr, alternatively about 400 Torr to about 550 Torr, alternatively about 500 Torr to about 760 Torr, alternatively about 100 Torr to about 760 Torr. The redox operation of operation 330 may be performed for about 1 second (s) to about 360 s, such as about 60 s to about 300 s, such as about 120 s to about 240 s, alternatively about 1 s to about 60 s, alternatively about 60 s to about 120 s, alternatively about 120 s to about 180 s, alternatively about 180 s to about 240 s, alternatively about 240 s to about 300 s, alternatively about 300 s to about 360 s.

In some embodiments, the redox operation is a microwave assisted redox operation. A microwave assisted redox operation may include applying a microwave energy to the process gas during the redox operation. In at least one embodiment, the microwave energy applied during the microwave assisted redox operation is provided at a power level at which the delivered microwave energy does not generate a plasma. Without being bound by theory, the delivery of microwave energy that is at a non-plasma generating power level can significantly reduce the amount of damage to the materials (e.g., dielectric and metal materials) in the substrate due to plasma generated ion bombardment of the materials within the substrate. By using a non-plasma generating mode, the damage can be 10% to 50% lower than the plasma mode, as the energetic species (e.g., hydrogen radicals and ions) are not introduced during the process. In one example, a non-plasma generating power level includes a microwave energy power level that is between 1% and 10% below a lowest power level that generates a plasma during a process that includes a desired gas composition and pressure level. However, in at least one embodiment, applying the microwave energy to the process gas induces a plasma within the processing chamber for at least a portion of the processing time.

The microwave energy applied to the process gas during the microwave assisted redox operation may be applied at a power of about 250 W to about 5000 W, such as about 500 W to about 2500 W, such as about 1000 W to about 2000 W, such as about 1250 W to about 1750 W at a frequency between about 2.0 GHz and 2.5 GHz, such as about 2.2 GHz to about 2.5 GHz, such as about 2.4 GHz to about 2.5 GHz. The microwave energy may be applied to the process gas continuously throughout the microwave assisted redox operation. In at least one embodiment, the microwave assisted redox operation includes applying the microwave energy to the process gas for about 1 s to about 360 s, such as about 60 s to about 300 s, such as about 120 s to about 240 s, alternatively about 1 s to about 60 s, alternatively about 60 s to about 120 s, alternatively about 120 s to about 180 s, alternatively about 180 s to about 240 s, alternatively about 240 s to about 300 s, alternatively about 300 s to about 360 s.

In some embodiments, the pressure within the processing chamber during the microwave assisted redox operation is about 10 mTorr to about 500 mTorr, such as about 50 mTorr to about 400 mTorr, such as about 100 mTorr to about 300 mTorr, such as about 150 mTorr to about 250 mTorr, alternatively about 10 mTorr to about 50 mTorr, alternatively about 50 mTorr to about 100 mTorr, alternatively about 100 mTorr to about 150 mTorr, alternatively about 150 mTorr to about 200 mTorr, alternatively about 200 mTorr to about 250 mTorr, alternatively about 250 mTorr to about 300 mTorr, alternatively about 300 mTorr to about 400 mTorr, alternatively about 400 mTorr to about 500 mTorr.

In some embodiments, the temperature within the processing chamber during the microwave assisted redox operation is in a range from about 100° C. to about 500° C., such as about 200° C. to about 400° C., such as about 250° C. to about 350° C., alternatively about 100° C. to about 200° C., alternatively about 200° C. to about 250° C., alternatively about 250° C. to about 300° C., alternatively about 300° C. to about 350° C., alternatively about 350° C. to about 400° C., alternatively about 400° C. to about 500° C.

The process gas may be flowed into the processing chamber at a gas flow rate of about 5 sccm to about 500 sccm during the microwave assisted redox operation, such as about 10 sccm to about 400 sccm, such as about 50 sccm to about 300 sccm, such as about 100 sccm to about 200 sccm, alternatively about 5 sccm to about 10 sccm, alternatively about 10 sccm to about 50 sccm, alternatively about 50 sccm to about 100 sccm, alternatively about 100 sccm to about 150 sccm, alternatively about 150 sccm to about 200 sccm, alternatively about 200 sccm to about 300 sccm, alternatively about 300 sccm to about 400 sccm, alternatively about 400 sccm to about 500 sccm. In at least one embodiment, the process gas is flown into the processing chamber continuously throughout the duration of the microwave assisted redox operation.

Upon completion of operation 340 of the method 300, about 95% or greater of the metal oxide is reduced to the base metal component (e.g., MoOx is reduced to Mo), such as about 97.5% or greater, such as about 99% or greater, such as about 99.9% or greater. In at least one embodiment, substantially all of the metal oxide within the metal oxide layer 412 is reduced to the metal material of the metal layer 410, thereby substantially regenerating the metal layer 410 to its initial thickness as illustrated by the semiconductor structure 400d shown in FIG. 4D. As such, the metal layer 410 of the semiconductor structure 400d may be in contact with the barrier layer 414 disposed thereon.

In operation 350 of the method 300, the semiconductor structure 400d is subjected to a thermal annealing process within a hydrogen environment in a suitable processing chamber to ensure substantial reduction of the metal oxide layer 412 and/or substantial regeneration of the metal layer 410. Additionally or alternatively, the thermal annealing process is conducted to substantially remove any byproducts resulting from the redox operation from the semiconductor structure 400d.

In some embodiments, the temperature within the processing chamber during the thermal annealing process is about 100° C. to about 500° C., such as about 150° C. to about 450° C., such as about 200° C. to about 400° C., such as about 250° C. to about 350° C., alternatively about 100° C. to about 150° C., alternatively about 150° C. to about 200° C., alternatively about 200° C. to about 250° C., alternatively about 250° C. to about 300° C., alternatively about 300° C. to about 350° C., alternatively about 350° C. to about 400° C., alternatively about 400° C. to about 450° C., alternatively about 450° C. to about 500° C. The pressure within the processing chamber during the thermal annealing process may be from about 10 Torr to about 760 Torr, such as about 250 Torr to about 760 Torr, such as about 250 Torr to about 530 Torr, alternatively about 10 Torr to about 100 Torr, alternatively about 100 Torr to about 250 Torr, alternatively about 250 Torr to about 400 Torr, alternatively about 400 Torr to about 550 Torr, alternatively about 500 Torr to about 760 Torr, alternatively about 100 Torr to about 760 Torr. The thermal annealing process of operation 350 may be performed for about 1 second (s) to about 360 s, such as about 60 s to about 300 s, such as about 120 s to about 240 s, alternatively about 1 s to about 60 s, alternatively about 60 s to about 120 s, alternatively about 120 s to about 180 s, alternatively about 180 s to about 240 s, alternatively about 240 s to about 300 s, alternatively about 300 s to about 360 s.

Hydrogen gas may be flowed into the processing chamber at a gas flow rate of about 10 sccm to about 500 sccm during the thermal annealing process, such as about 50 sccm to about 400 sccm, such as about 100 sccm to about 300 sccm, alternatively about 10 sccm to about 50 sccm, alternatively about 50 sccm to about 100 sccm, alternatively about 100 sccm to about 200 sccm, alternatively about 200 sccm to about 300 sccm, alternatively about 300 sccm to about 400 sccm, alternatively about 400 sccm to about 500 sccm. In at least one embodiment, the hydrogen gas is flown into the processing chamber continuously throughout the duration of the thermal annealing process.

Conventional semiconductor fabrication processes incorporating Mo as the metal layer typically do not involve intentionally generating a metal oxide (e.g., MoOx) layer at or on the surface of the metal layer, nor the subsequent redox operation. Generally, such conventional processes include a cleaning operation (e.g., a chemical clean and/or a plasma clean) to remove any unintentionally formed metal oxides therefrom prior to depositing the barrier layer (e.g., a TaN barrier layer) via an ALD process. However, the nitrogen precursor provided during the ALD process can react with the Mo within the metal layer to form molybdenum nitride (MoN). Generation of MoN within the metal layer can result in increased resistance and reduced device performance. In contrast, the process disclosed herein integrates the formation of the metal oxide (e.g., MoOx) layer on the exposed surface of the metal layer of the semiconductor structure. The metal oxide layer prevents the nitrogen precursor provided during the subsequent barrier layer ALD process from reacting with the metal layer thereby mitigating MoN formation. Furthermore, the subsequent microwave assisted redox operation allows for reduction of the metal oxide layer (e.g., MoOx) to regenerate the initial metal layer without affecting the barrier layer deposited thereon.

Overall, the present disclosure provides a method for preparing a semiconductor device that integrates a Mo metal layer. The process disclosed herein incorporates various fabrication operations, which are organized to mitigate Mo nitridation thereby improving device performance. The method includes depositing metal layer onto a semiconductor structure, exposing the semiconductor structure to an air break to form a metal oxide layer on the metal layer, depositing a barrier layer over the surface of the semiconductor structure, performing a microwave assisted redox on the semiconductor structure, and annealing the semiconductor structure in a hydrogen environment. Unlike conventional fabrication processes for preparing a semiconductor device that integrates a Mo metal layer, the process disclosed herein integrates the formation of the metal oxide (e.g., MoOx) layer on the exposed surface of the metal layer to prevent nitrogen based reagents of subsequent processing operation from reacting with the metal layer to form MoN. Furthermore, the method disclosed herein integrates a microwave assisted redox operation to allow for reduction of the metal oxide layer (e.g., MoOx) to regenerate the initial metal layer without affecting a barrier layer deposited thereon.

While the foregoing is directed to embodiments of the present disclosure, other and further embodiments of the disclosure may be devised without departing from the basic scope thereof, and the scope thereof is determined by the claims that follow.

What is claimed is:

1. A method for preparing a semiconductor device, comprising:
depositing a molybdenum (Mo) layer onto a substrate, wherein a portion of the Mo layer is exposed at a surface of the substrate;
exposing the substrate to an air break to form a molybdenum oxide (MoOx) layer on the exposed portion of the Mo layer;
depositing a tantalum nitride (TaN) layer on the surface of the substrate, the TaN layer contacting the MoOx layer; and
performing a microwave assisted redox operation on the substrate to regenerate the Mo layer from the MoOx layer, wherein performing the microwave assisted redox operation comprises:
positioning the substrate within a processing chamber,
flowing a process gas into the processing chamber, and
applying a non-plasma generating microwave energy to the process gas.

2. The method of claim 1, wherein the non-plasma generating microwave energy is applied to the process gas at a power of about 250 W to about 5000 W.

3. The method of claim 1, wherein the process gas is flown into the processing chamber at a gas flow rate of about 10 sccm to about 500 sccm.

4. The method of claim 1, wherein the process gas comprises hydrogen gas.

5. The method of claim 1, wherein a pressure within the processing chamber during the microwave assisted redox operation is about 10 mTorr to about 500 mTorr.

6. The method of claim 1, wherein a temperature within the processing chamber during the microwave assisted redox operation is about 100° C. to about 500° C.

7. A method for preparing a semiconductor device, comprising:
depositing a molybdenum (Mo) layer onto a substrate, wherein a portion of the Mo layer is exposed at a surface of the substrate, wherein the Mo layer is deposited in a first processing chamber;
exposing the substrate to an air break to form a molybdenum oxide (MoOx) layer on the exposed portion of the Mo layer;
depositing a tantalum nitride (TaN) layer on the surface of the substrate, the TaN layer contacting the MoOx layer, wherein the TaN layer is deposited in a second processing chamber; and
performing a microwave assisted redox operation on the substrate to regenerate the Mo layer from the MoOx layer, wherein performing the microwave assisted redox operation comprises:
positioning the substrate within a third processing chamber,
flowing a process gas into the third processing chamber, and
applying a non-plasma generating microwave energy to the process gas.

8. The method of claim 7, wherein the non-plasma generating microwave energy is applied to the process gas at a power of about 250 W to about 5000 W.

9. The method of claim 7, wherein the process gas is flown into the processing chamber at a gas flow rate of about 10 sccm to about 500 sccm.

10. The method of claim 7, wherein the process gas comprises hydrogen gas.

11. The method of claim 7, wherein a pressure within the processing chamber during the microwave assisted redox operation is about 10 mTorr to about 500 mTorr.

12. The method of claim 7, wherein a temperature within the processing chamber during the microwave assisted redox operation is about 100° C. to about 500° C.

13. A method for preparing a semiconductor device, comprising:
depositing a metal layer onto a substrate, wherein a portion of the metal layer is exposed at a surface of the substrate;
exposing the substrate to an air break to form a metal oxide layer on the exposed portion of the metal layer;
depositing a barrier layer on the surface of the substrate, the barrier layer contacting the metal oxide layer; and
performing a microwave assisted redox operation on the substrate to regenerate the metal layer from the metal oxide layer, wherein performing the microwave assisted redox operation comprises:
positioning the substrate within a processing chamber,
flowing a process gas into the processing chamber, and
applying a non-plasma generating microwave energy to the process gas.

14. The method of claim 13, wherein the non-plasma generating microwave energy is applied to the process gas at a power of about 250 W to about 5000 W.

15. The method of claim 13, wherein the process gas is flown into the processing chamber at a gas flow rate of about 10 sccm to about 500 sccm.

16. The method of claim 13, wherein the process gas comprises hydrogen gas.

17. The method of claim 13, wherein a pressure within the processing chamber during the microwave assisted redox operation is about 10 mTorr to about 500 mTorr.

18. The method of claim 13, wherein a temperature within the processing chamber during the microwave assisted redox operation is about 100° C. to about 500° C.

19. The method of claim 13, wherein the metal layer comprises molybdenum (Mo), tungsten (W), ruthenium (Ru), copper (Cu), cobalt (Co), tantalum (Ta), titanium (Ti), or a combination thereof.

20. The method of claim 13, wherein the barrier layer comprises tantalum nitride (TaN).
